(19) United States
(12) Patent Application Publication
(10) Pub. No.: US 2016/0072045 A1
(43) Pub. Date: Mar. 10, 2016

(54) MAGNETIC MEMORY AND METHOD FOR MANUFACTURING THE SAME

(71) Applicants: Hiroyuki KANAYA, Seoul (KR); Hisanori AIKAWA, Seoul (KR); Keisuke NAKATSUKA, Seoul (KR)

(72) Inventors: Hiroyuki KANAYA, Seoul (KR); Hisanori AIKAWA, Seoul (KR); Keisuke NAKATSUKA, Seoul (KR)

(21) Appl. No.: 14/593,611

(22) Filed: Jan. 9, 2015

Related U.S. Application Data
(60) Provisional application No. 62/047,498, filed on Sep. 8, 2014.

(51) Int. Cl. H01L 43/08; H01L 43/12; H01L 27/22

(52) U.S. Cl. CPC H01L 43/08; H01L 27/222; H01L 43/12

(57) ABSTRACT

According to one embodiment, a magnetic memory is disclosed. The magnetic memory comprises an interconnect layer, a first conductive layer on the interconnect layer, the first conductive layer including a metal, an oxide layer on the first conductive layer, a second conductive layer on the oxide layer, a magnetoresistive element on the second conductive layer, the magnetoresistive element including a first magnetic layer, a second magnetic layer and a nonmagnetic layer between the first and second magnetic layers, and a deposited material on a sidewall of the oxide layer, the deposited material including the metal.

### CROSS-REFERENCE TO RELATED APPLICATIONS

This application claims the benefit of U.S. Provisional Application No. 62/047,498, filed Sep. 8, 2014, the entire contents of which are incorporated herein by reference.

### FIELD

Embodiments described herein relate generally to a magnetic memory and a method for manufacturing the same.

### BACKGROUND

In recent years, a semiconductor memory using a variable resistance element as a storage element, for example, a phase-change random access memory (PRAM) or a magnetic random access memory (MRAM), has been attracting attention and been developed. The MRAM is a device which performs a memory operation by storing binary 1 or 0 in a memory cell by using magnetoresistance, and features nonvolatility, high-speed operation, high integration, and high reliability.

One of the magnetoresistive elements is a magnetic tunnel junction (MTJ) element including a three-layer laminated structure of a storage layer having a variable magnetization direction, an insulator film as a tunnel barrier and a reference layer maintaining a predetermined magnetization direction.

The resistance of the MTJ element varies with the magnetization directions of the storage layer and the reference layer, and has a minimum value when the magnetization directions are parallel and a maximum value when the magnetization directions are antiparallel. These parallel and antiparallel states are associated with binary 0 and 1, and data is thereby stored.

There are schemes for writing data to the MTJ element: one is a magnetic field writing scheme in which only the magnetization direction of the storage layer is reversed by a current magnetic field generated when a current is passed through a writing interconnect; and another is a writing (spin injection writing) scheme using spin angular momentum transfer in which the magnetization direction of the storage layer is reversed by passing a spin-polarized current through the MTJ element itself.

In the former scheme, the smaller the element size is, the greater the coercivity of a magnetic body constituting the storage layer is. Thus, a write current tends to increase and it is hard to achieve both miniaturization and low current.

On the other hand, in the latter scheme (spin injection writing scheme), the smaller the volume of a magnetic layer constituting the storage layer is, the smaller the number spin-polarized electrons to be injected is. Thus, it is expected that both miniaturization and low current can be easily achieved.

### BRIEF DESCRIPTION OF THE DRAWINGS

FIG. 1 is a perspective view showing a magnetic memory according to a first embodiment;

FIG. 2A, FIG. 2B, FIG. 2C, FIG. 2D, FIG. 2E, FIG. 3, FIG. 4, FIG. 5, FIG. 6 and FIG. 7 are sectional views showing a method for manufacturing the magnetic memory of FIG. 1;

FIG. 8, FIG. 9, FIG. 10 and FIG. 10A are sectional views showing a modification of the method for manufacturing the magnetic memory of FIG. 1;

FIG. 11 is a sectional view showing a magnetic memory according to a second embodiment;

FIG. 12 and FIG. 13 are sectional views showing a method for manufacturing the magnetic memory of FIG. 11;

FIG. 14 and FIG. 14A are sectional views showing a modification of the method for manufacturing the magnetic memory of FIG. 11;

FIG. 15 is a sectional view showing a magnetic memory according to a third embodiment;

FIG. 16A, FIG. 16B, FIG. 16C, FIG. 16D and FIG. 16E are sectional view showing a method for manufacturing the magnetic memory of FIG. 15;

FIG. 17 and FIG. 17A are sectional views showing a modification of the method for manufacturing the magnetic memory of FIG. 15;

FIG. 18, FIG. 19 and FIG. 19A are sectional views showing a magnetic memory according to a fourth embodiment; and

FIG. 20, FIG. 21, FIG. 21A, FIG. 22, FIG. 23 and FIG. 23A are sectional views showing a magnetic memory according to a fifth embodiment.

### DETAILED DESCRIPTION

In general, according to one embodiment, a magnetic memory is disclosed. The magnetic memory comprises: an interconnect layer; a first conductive layer on the interconnect layer, the first conductive layer including a metal; an oxide layer on the first conductive layer; a second conductive layer on the oxide layer; a magnetoresistive element on the second conductive layer, the magnetoresistive element including a first magnetic layer, a second magnetic layer and a nonmagnetic layer between the first and second magnetic layers; and a deposited material on a sidewall of the oxide layer, the deposited material including the metal.

Magnetic memories of embodiments will be described hereinafter according to methods for manufacturing the same with reference to the accompanying drawings. In the drawings, the same portions are given the same reference numbers.

### First Embodiment

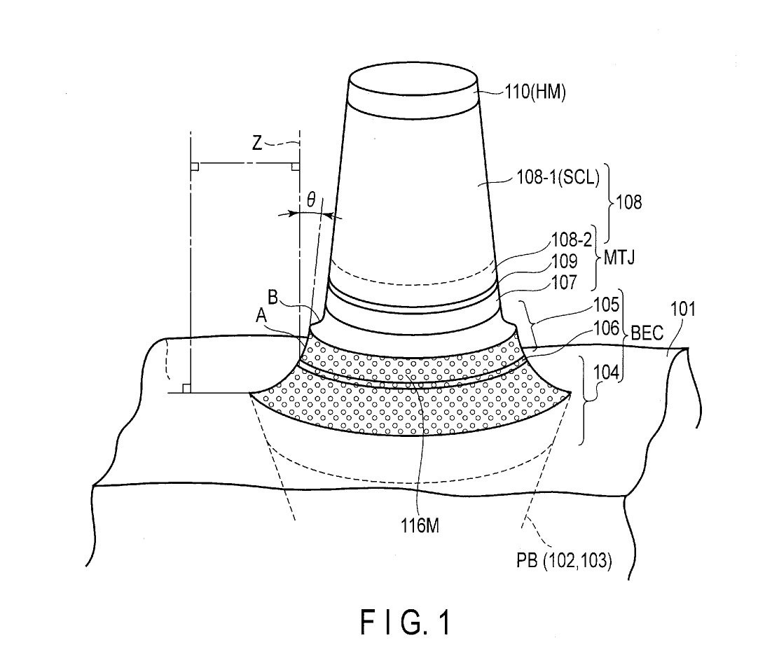

FIG. 1 to FIG. 7 are sectional views for explaining a magnetic memory and a method for manufacturing the same according to a present embodiment. In the present embodiment, the case where the magnetic memory is a magnetic random access memory (MRAM) will be described.

### Magnetic Memory

First, the magnetic memory will be described with reference to FIG. 1.

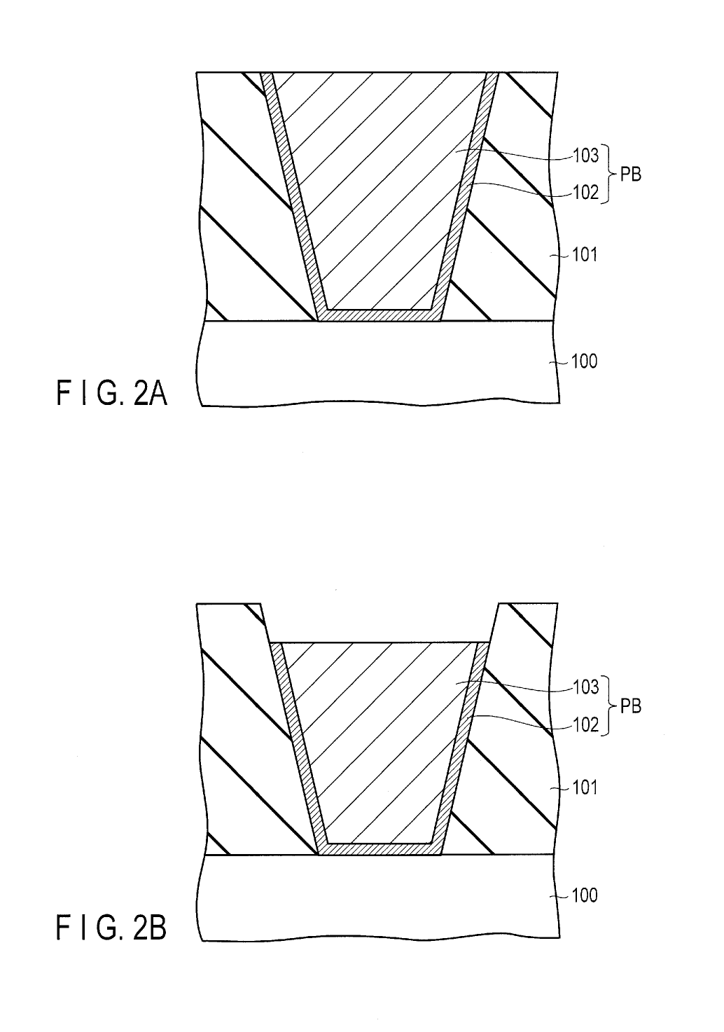

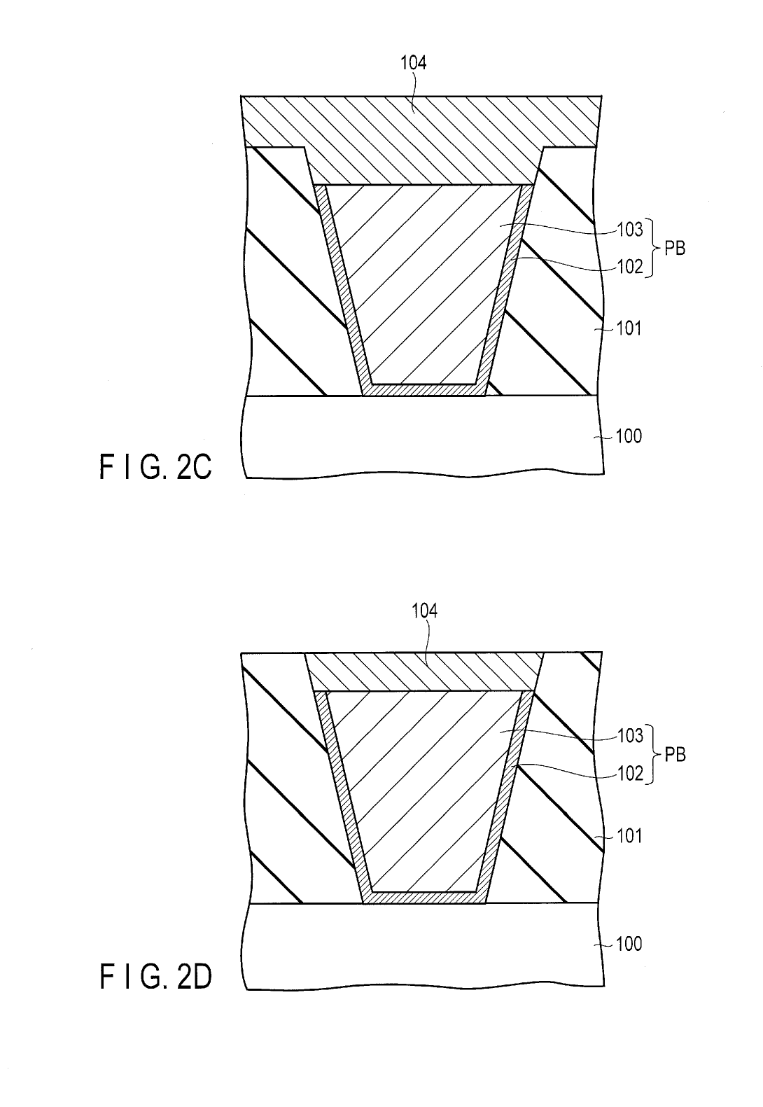

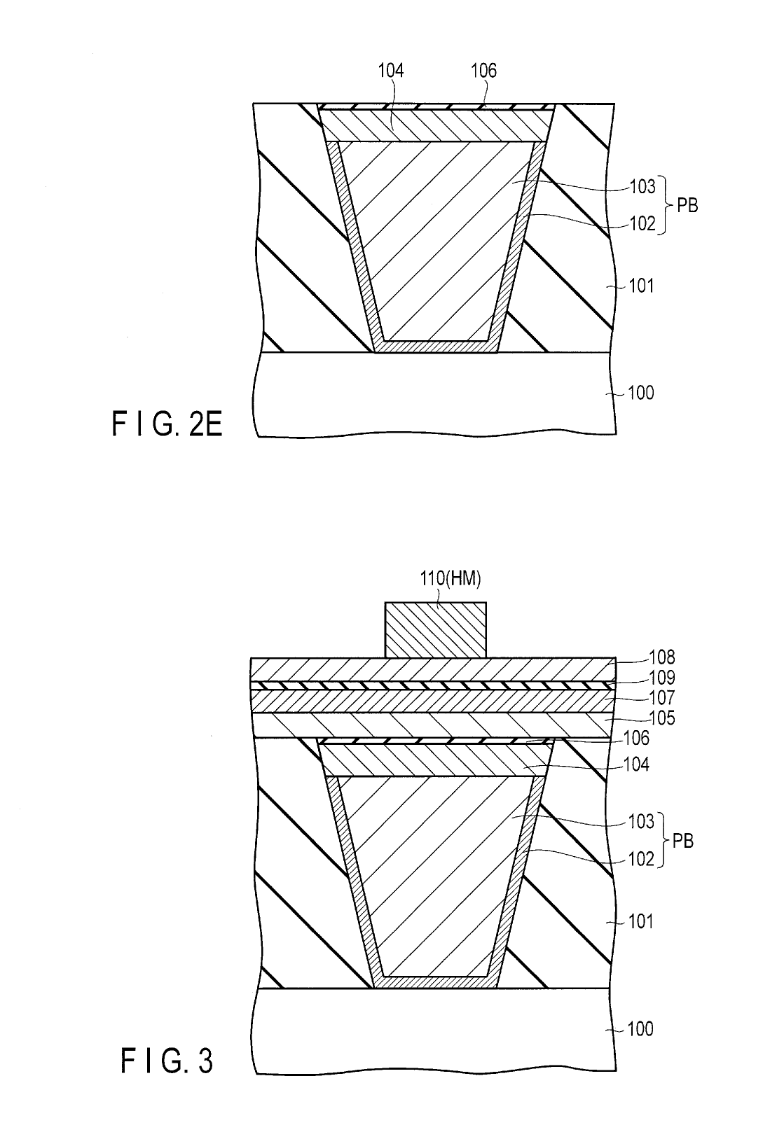

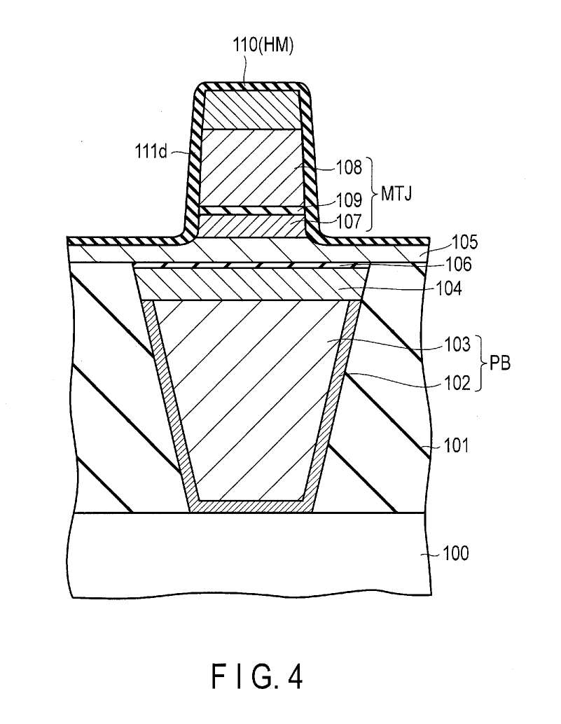

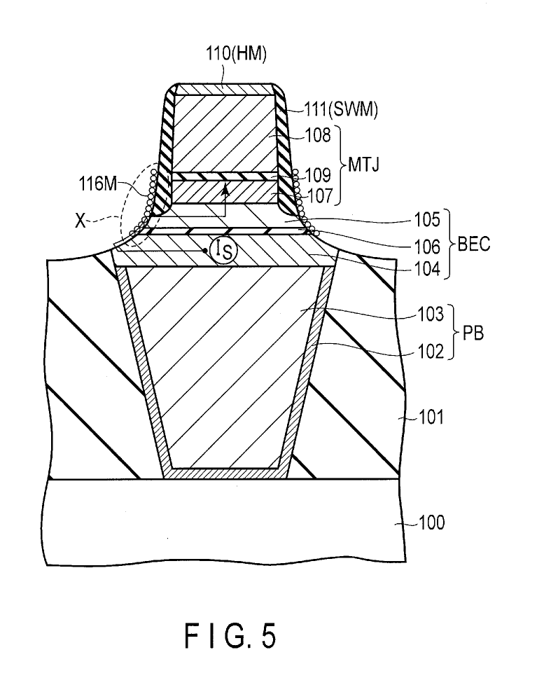

In FIG. 1, such elements as a wafer 100, a sidewall mask (sidewall insulator) layer (SWM) 111 and a passivation layer (PL) 112, disclosed in FIG. 2 and the subsequent figures, are omitted to clarify a positional relationship between elements 101 to 110 and 116M in FIG. 1.

An interconnect layer PB (102, 103) is, for example, a contact plug. A first conductive layer 104 is disposed on the interconnect layer PB (102, 103).

The first conductive layer 104 includes a crystalline metal which can form an oxide by oxidation treatment, for example, Ta, Ir or Ru. The first conductive layer 104 may be a compound. The first conductive layer 104 functions also as an anti-diffusion layer.

A second conductive layer 105 (buffer layer) is disposed as a ground of a magnetoresistive element MTJ, and improves the crystallinity of the magnetoresistive element MTJ. In addition, the second conductive layer 105 is an orientation control layer for forming a magnetic layer formed on the second conductive layer 105. The second conductive layer 105 includes a conductive metal, for example, Hf, Al, Be, Mg, Ca, Sr, Ba, Sc, Y, La, or Zr. The second conductive layer 105 may be a metal compound. The second conductive layer 105 may be omitted, provided that the first conductive layer 104 and the magnetoresistive element MTJ are electrically connected.

The second conductive layer 105 comprises a first sidewall A being in contact with an oxide layer 106 and a second sidewall B which retreats from the first sidewall A and is located above the first sidewall A. Here, each of the first and second sidewalls A and B has a tilt with respect to an axis Z vertical to the top surface of the first conductive layer 104. For example, they have a tilt θ of 15° or less.

The oxide layer 106 is disposed between the first and second conductive layers 104 and 105. The oxide layer 106 is an oxide of the first conductive layer 104 and includes an amorphous state.

The oxide layer 106 is in the amorphous state, and thus, compensates a crystallization defect, for example a void or a seam, of the first conductive layer 104 disposed directly thereunder. More specifically, the oxide layer 106 in the amorphous state can make discontinuous the crystallinity between the first conductive layer 104 and the second conductive layer 105 disposed above and below the oxide layer 106. For example, the seam in the first conductive layer 104 is compensated by the oxide layer 106 in the amorphous state, and thus is not conducted to the second conductive layer 105. Consequently, the uniformity of the crystallinity of the second conductive layer 105 is improved, and the uniformity of the crystallinity of the magnetoresistive element MTJ is also improved.

The oxide layer 106 is a nonconductive oxide, for example, TaO_{X}, or a conductive oxide, for example, IrO_{X} or RuO_{X}.

If the nonconductive oxide is used as the oxide layer 106, a conductive deposited material, for example, a reattachment material 116M (indicated by marks ◯ in the figure), needs to be formed on a sidewall of the oxide layer 106, to make an electrical connection between the first conductive layer 104 and the second conductive layer 105.

On the other hand, if the conductive oxide is used as the oxide layer 106, the conductive deposited material may be formed or does not need to be formed on the sidewall of the oxide layer 106.

A lower electrode layer includes the first conductive layer 104, the oxide layer 106 and the second conductive layer 105.

The magnetoresistive element MTJ on the lower electrode layer comprises a first magnetic layer 107, a second magnetic layer 108, and a nonmagnetic layer (tunnel barrier layer) 109 between the first and second magnetic layers. One of the first and second magnetic layers 107 and 108 is a reference layer having invariable magnetization, and the other is a storage layer having variable magnetization.

Here, the invariable magnetization means that a magnetization direction does not vary before or after writing, and the variable magnetization means that the magnetization direction can vary in reverse before or after writing.

In addition, the writing means spin transfer writing in which a spin injection current (spin-polarized electron) is passed through the magnetoresistive element MTJ, and a spin torque is thereby given to the magnetization of a storage layer.

If the first magnetic layer 107 is a storage layer and the second magnetic layer 108 is a reference layer, the magnetoresistive element MTJ is referred to as a top-pin type. In addition, if the first magnetic layer 107 is a reference layer and the second magnetic layer 108 is a storage layer, the magnetoresistive element MTJ is referred to as a bottom-pin type.

It is preferable that each of the first and second magnetic layers 107 and 108 have vertical magnetization, that is, residual magnetization in a vertical direction parallel to a direction in which the first and second magnetic layers 107 and 108 are stacked. However, each of the first and second magnetic layers 107 and 108 may have in-plane magnetization, that is, residual magnetization in an in-plane direction vertical to the direction in which the first and second magnetic layers 107 and 108 are stacked.

The first and second magnetic layers 107 and 108 comprise, for example, CoFeB, MgFeO, or a stack of these. In the case of a magnetoresistive element MTJ having vertical magnetization, it is preferable that the first and second magnetic layers 107 and 108 comprise CoFeb having vertical magnetic anisotropy, TbCoFe, an artificial lattice in which Co and Pt are stacked together, L1o-ordered FePt, etc. In this case, CoFeB as an interface layer may be provided between the first magnetic layer 107 and the nonmagnetic layer 109, or between the nonmagnetic layer 109 and the second magnetic layer 108.

The nonmagnetic layer 109 comprises, for example, MgO or AlO. The nonmagnetic layer 109 may be nitride such as Al, Si, Be, Mg, Ca, Sr, Ba, Sc, Y, La, Zr or Hf.

A third conductive layer (HM) 110 is disposed on the magnetoresistive element MTJ. The third conductive layer (HM) 110 comprises, for example, W, Ta, Ru, Ti, TaN or TiN.

In addition to functioning as an electrode, the third conductive (hard mask) layer (HM) 110 functions as a mask at the time of patterning the magnetoresistive element MTJ. That is, it is preferable that the third conductive layer (HM) 110 comprise a material which has low resistivity and high diffusion, etching and milling tolerances, for example, a stack of Ta and Ru.

In addition, a layer constituting the MTJ is, for example, a shift cancelling layer SCL (18-1 in FIG. 1). The shift cancelling layer SCL (18-1) is formed, for example (as indicated by a broken line in FIG. 1), on a portion (18-2 in FIG. 1) of the reference layer or the storage layer, within the second magnetic layer 108.

In this case, the second magnetic layer 108 includes the shift cancelling layer SCL (18-1) on the portion (18-2) of the reference layer or the storage layer.

If the second magnetic layer 108 includes the shift cancelling layer SCL (18-1), the third conductive layer (HM) 110 is formed on the shift cancelling layer SCL (18-1).

In the present embodiment, the plane pattern of the magnetoresistive element MTJ is circular. However, the plane pattern of the magnetoresistive element MTJ is not limited to this, and may be, for example, rectangular. In the present embodiment, because the laminated body of the layers 107, 108 and 109 constituting the magnetoresistive element MTJ has a tapered shape which narrows toward the top, the diameter of the first magnetic layer 107 is the largest among the layers 107, 108 and 109 constituting the magnetoresistive element MTJ.

### Manufacturing Method

Next, a method for manufacturing the magnetic memory in the case where the oxide layer 106 of FIG. 1 is nonconductive will be described with reference to FIG. 2 to FIG. 7.

### [FIG. 2A-FIG. 2E]

First, as shown in FIG. 2A-FIG. 2E, an interlayer insulating layer 101 is formed on the wafer (for example, a silicon wafer) 100, and then, a contact plug 103 is formed in the interlayer insulating layer 101 through a barrier metal layer 102 by an embedding process. The interconnect layer PB includes the barrier metal layer 102 and the contact plug 103.

The interlayer insulating layer 101 is, for example, a silicon oxide layer (SiO₂). The barrier metal layer 102 includes, for example, a stack of Ti and TiN. The contact plug 103 includes, for example, W or TiN. Depending on the material of the contact plug 103, the barrier metal layer 102 may be unnecessary.

A selection transistor not shown in the figure is formed on the wafer 100. The selection transistor is an element for selecting the magnetoresistive element MTJ. The selection transistor is, for example, a surrounding gate transistor (SGT). A gate insulating layer of the SGT and a gate electrode are embedded in the wafer 100. The contact plug 103 is connected to, for example, a source/drain region of the selection transistor.

The interconnect layer PB is formed by an embedding process and a flattening process (CMP). Then, the interconnect layer PB is recessed and etched back, and the surface of the contact plug 103 is etched by approximately 20 to 30 nm. By such a method, a hole is formed in the interconnect layer PB. The first conductive layer 104 is deposited in the hole, and then is annealed. Then, by a chemical mechanical polishing (CMP) process, the surface of the first conductive layer 104 is flattened. The first conductive layer 104 is, for example, crystalline Ta (for example, having a thickness of up to 20 nm).

Next, the first conductive layer 104 is oxidized by a wet process, etc., and the oxide layer 106 in an amorphous state is formed. The oxide layer 106 is, for example, amorphous TaO_{X} (for example, having a thickness of 2 to 5 nm).

### [FIG. 3]

Next, as shown in FIG. 3, the second conductive layer 105 (for example, Hf having a thickness of 5 nm) is formed on the oxide layer 106, and the first magnetic layer 107 is formed on the second conductive layer 105.

Next, the nonmagnetic layer 109 (for example, MgO having a thickness of 1 nm) is formed on the first magnetic layer 107, and the second magnetic layer 108 is formed on the nonmagnetic layer 109. The first and second magnetic layers 107 and 108 are formed by, for example, a sputtering process.

A layer constituting the MTJ except the first magnetic layer 107, the nonmagnetic layer 109 and the second magnetic layer 108 is, for example, a shift cancelling layer SCL. The shift cancelling layer SCL is formed, for example, on the second magnetic layer 108. Here, the SCL is not shown in the figure.

Next, the third conductive (hard mask) layer (HM) 110 is formed on the second magnetic layer 108. If the shift cancelling layer SCL is on the second magnetic layer 108, the third conductive layer (HM) 110 is formed on the shift cancelling layer SCL.

### [FIG. 4]

Next, as shown in FIG. 4, with the third conductive layer (HM) 110 used as a mask, the second magnetic layer 108, the nonmagnetic layer 109 and the first magnetic layer 107 are etched successively to form the magnetoresistive element MTJ. This etching may be carried out until the second conductive layer within 105. In addition, the etching may be stopped at the surface of the second conductive layer 105.

Then, an insulating layer 111d covering the magnetoresistive element MTJ, the third conductive layer 110 and the second conductive layer 105 is formed by, for example, CVD. The insulating layer 111d is, for example, a silicon nitride layer SiN.

### [FIG. 5]

Next, as shown in FIG. 5, the insulating layer 111d is etched by, for example, reactive ion etching (RIE) to form the sidewall mask layer (SWM) 111.

The sidewall mask layer (SWM) 111 covers a part of a sidewall of the second conductive layer 105, a sidewall of the magnetoresistive element MTJ and a sidewall of the third conductive layer (HM) 110.

After that, with the third conductive layer (HM) 110 and the sidewall mask layer (SWM) 111 used as masks, the second conductive layer 105, the oxide layer 106 and the first conductive layer 104 are etched to form the lower electrode layer.

Here, the first conductive layer 104 to be a bottom layer is etched by physical etching such as ion beam etching (IBE).

In this etching, a part of an element in the first conductive layer 104, which has been once etched, is reattached to a sidewall of the lower electrode layer, and thus, the reattachment material 116M is formed thereon (marks o in dotted-line circle X in the figure). The reattachment material 116M is a conductive material including the element in the first conductive layer 104, and thus, electrically connects the first and second conductive layers 104 and 105. The reattachment material 116M is referred to as a local interconnect.

The reattachment material 116M needs to be formed at least on the sidewall of the nonconductive oxide layer 106 in order to electrically connect the first and second conductive layers 104 and 105 by the reattachment material 116M. In the figure, I_{S} indicates a current path. The current path I_{S} leads from the first conductive layer 104 to the second conductive layer 105 through the reattachment material (local interconnect) 116M.

### [FIG. 6]

Next, as shown in FIG. 6, the passivation layer (PL) 112 is formed after the reattachment material 116M is formed. The passivation layer (PL) 112 covers the interlayer insulating layer 101, the lower electrode layer, the reattachment material 116M, the sidewall mask layer (SWM) 111, and the third conductive layer (HM) 110.

The physical etching of FIG. 5 and the formation of the passivation layer (PL) 112 of FIG. 6 are carried out in different chambers (multi-chamber apparatus). It should be noted a space between the respective chambers is kept in a vacuum. Thus, a wafer can be conveyed in a vacuum between the different chambers. The passivation layer (PL) 112 includes, for example, an insulating layer such as SiN or SiO₂.

### [FIG. 7]

Next, as shown in FIG. 7, an interlayer insulating layer 113 is formed on the whole surface of the passivation layer (PL) 112. Then, the surface of the interlayer insulating layer 113 is flattened by a CMP process. The interlayer insulating layer 113 is, for example, a silicon oxide layer SiO₂. The interlayer insulating layer 113 is formed by, for example, a plasma CVD process.

Next, by using an embedding process, an upper electrode 114 for connecting to the third conductive layer (HM) 110 is formed in the interlayer insulating layer 113. A material for the upper electrode 114 is, for example, W. After that, an interlayer insulating layer 117 is formed on the interlayer insulating layer 113. By using an embedding process, an interconnect 115 for connecting to the upper electrode 114 is formed in the interlayer insulator 117. A material for the interconnect 115 is, for example, Cu. In this manner, the magnetic memory is completed.

As described above, according to the magnetic memory and the method for manufacturing the same of the present embodiment, the properties of the magnetoresistive element MTJ can be improved by the oxide layer (insulating layer) 106 between the first and second conductive layers 104 and 105. In addition, even if the oxide layer 106 exists between the first and second conductive layers 104 and 105, an electrical connection between the first and second conductive layers 104 and 105 can be made by the reattachment material 116M.

In the figure, L indicates a distance (margin) between the magnetoresistive element MTJ and the interconnect layer PB. The distance L is appropriately adjusted to electrically connect the interconnect layer PB and the magnetoresistive element MTJ. That is, the diameter of the first conductive layer 104 on the interconnect layer PB is made larger than that of the magnetoresistive element MTJ to allow a reattachment from the first conductive layer 104 to be easily attached.

### Modification

A modification of the above-described method for manufacturing the magnetic memory will be described.

In this modification, in addition to the reattachment material 116M, a sidewall interconnect layer 118N is further provided to make an electrical connection between the first and second conductive layers 104 and 105.

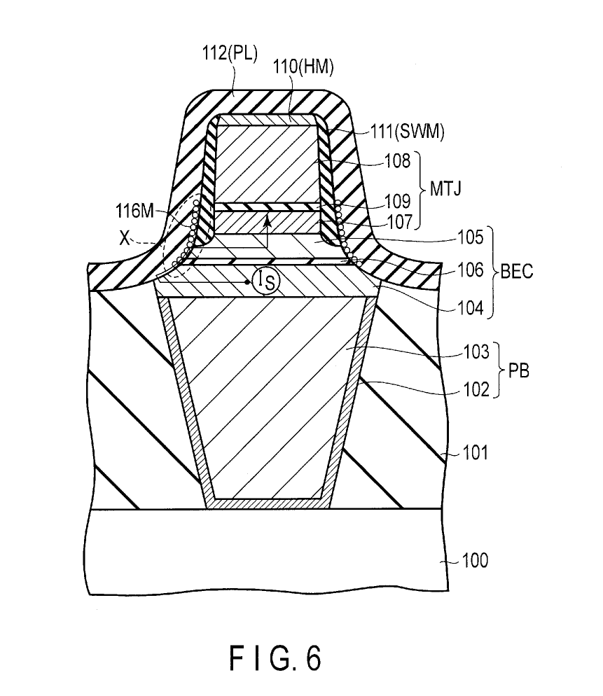

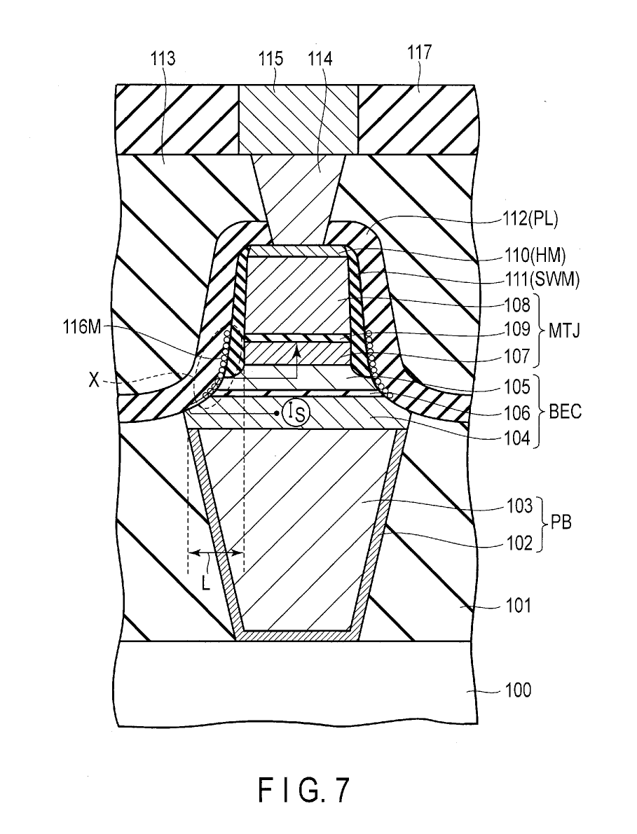

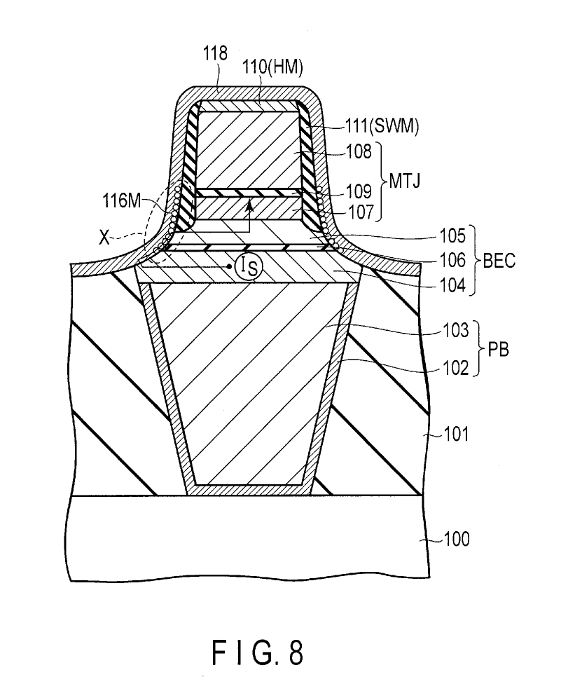

### [FIG. 8]

First, as shown in FIG. 8, the lower electrode layer is patterned by, for example, IBE, and the processes through which the reattachment material 116M is formed on the sidewall of the oxide layer 106 are carried out as in the embodiment shown in FIG. 2 to FIG. 5. After that, a conductive layer 118, for example, TiN, is formed. The conductive layer 118 covers the interlayer insulating layer 101, the lower electrode layer, the reattachment material 116M, the sidewall mask layer (SWM) 111 and the third conductive layer (HM) 110.

### [FIG. 9]

Next, as shown in FIG. 9, the whole surface of the conductive layer 118 are etched back, thereby forming the sidewall interconnect layer 118N covering the reattachment material 116M on the sidewall of the oxide layer 106. Because the sidewall interconnect layer 118N covers at least the sidewall of the nonconductive oxide layer 106, an electrical connection between the first and second conductive layers 104 and 105 can be surely made. The sidewall interconnect layer 118N may partly cover the sidewall mask layer (SWM) 111. The sidewall interconnect layer 118N is formed to become thicker toward a portion vertical to a top surface of the first conductive layer 104, and is formed to become thinner toward a portion forming a small taper angle with the top surface of the first conductive layer 104. Therefore, the sidewall interconnect layer 118N becomes thinner as it extends from the sidewall of the first conductive layer 104 to the sidewall of the sidewall mask layer (SWM) 111.

That is, the current path Is leads from the first conductive layer 104 to the second conductive layer 105 through the sidewall interconnect layer 118N and the reattachment material 116M.

### [FIG. 10]

Next, as shown in FIG. 10, by the same processes as those of the first embodiment shown in FIG. 6 and FIG. 7, the passivation layer (PL) 112, the interlayer insulating layer 113, the upper electrode 114, the interconnect 115 and the interlayer insulating layer 117 are formed to complete the magnetic memory.

According to this modification, the same advantage as that of the manufacturing method shown in FIG. 2 to FIG. 7 can be obtained. Moreover, according to this modification, because the reattachment material 116M is electrically reinforced by the sidewall interconnect layer 118N, an electrical connection between the first and second conductive layers 104 and 105 can be more surely made.

It should be noted that an electrical connection between the first and second conductive layers 104 and 105 can be made only by the sidewall interconnect layer 118N. Thus, as shown in FIG. 10A, in this modification, the reattachment material 116M may not be provided.

### Second Embodiment

A second embodiment relates to a magnetic memory formed by a so-called stop-on-tunnel-barrier process.

### Magnetic Memory

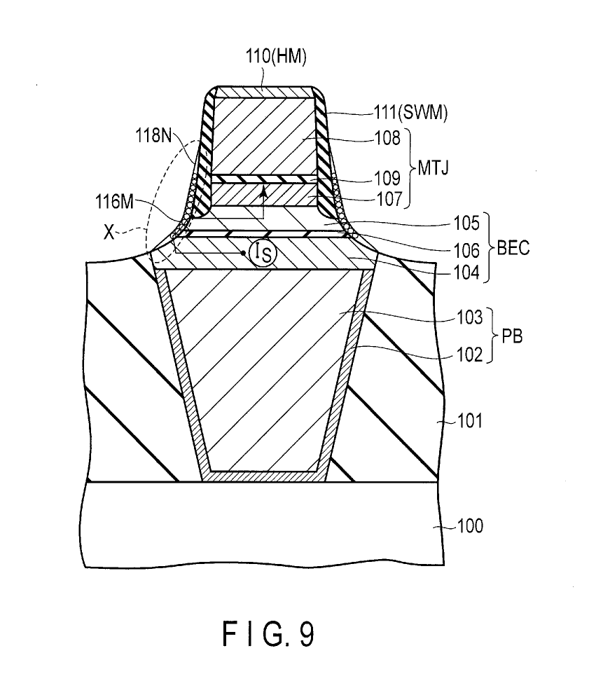

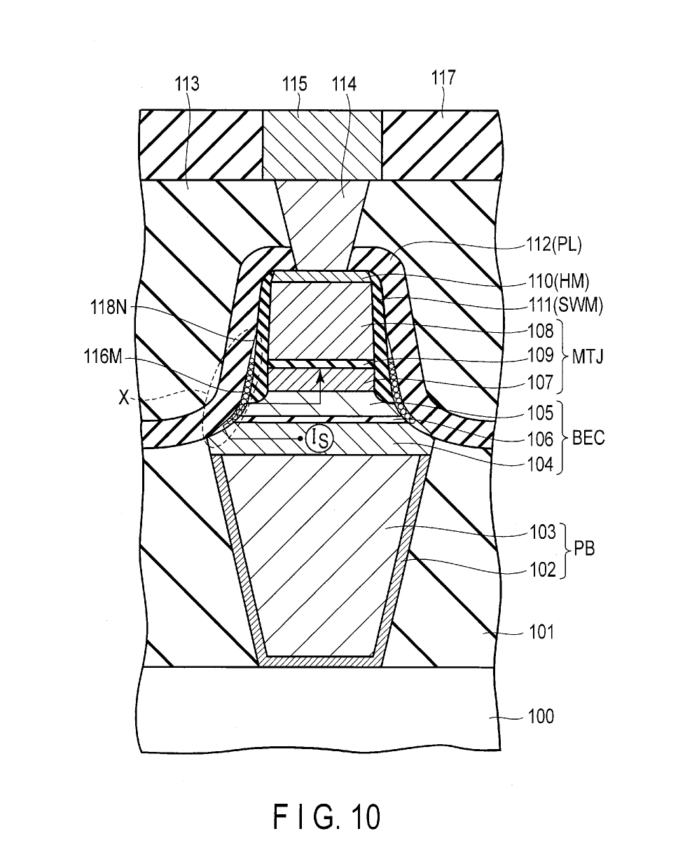

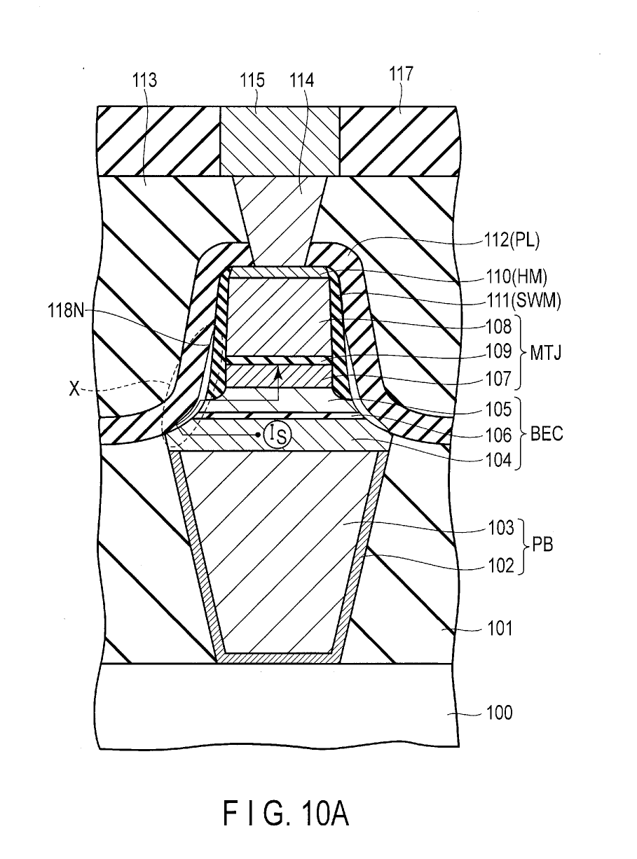

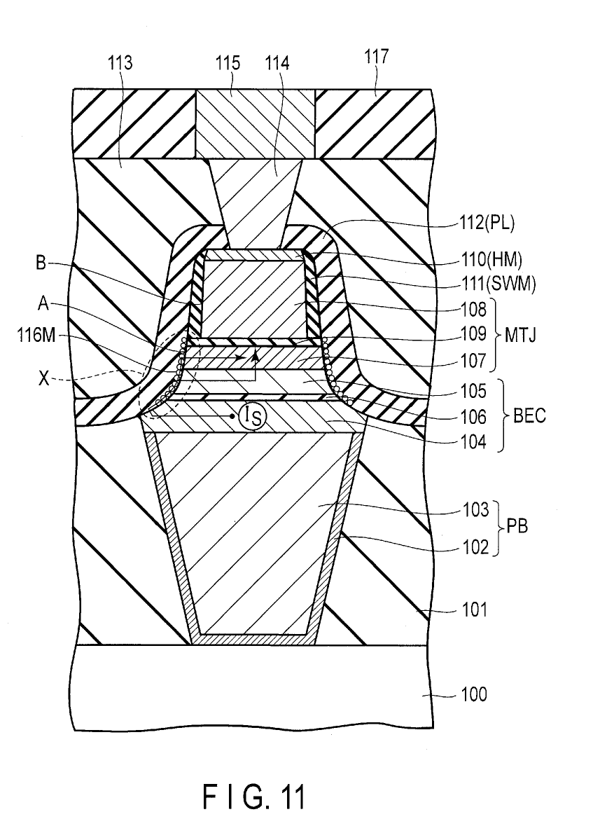

FIG. 11 shows the magnetic memory according to the second embodiment.

In the second embodiment, the positions of the first sidewall A and the second sidewall B differ from those in the first embodiment (FIG. 1). That is, in the second embodiment, because the stop-on-tunnel-barrier process is adopted, the boundary between the first and second sidewalls A and B is located in the nonmagnetic layer (tunnel barrier layer) 109 or in proximity thereto. In other words, the sidewall mask layer (SWM) 111 exists on the side surfaces of the third conductive layer (HM) 110 and the second magnetic layer 108, and stops on the nonmagnetic layer (tunnel barrier layer) 109.

Because the other points are the same as in the first embodiment, the same elements as those of the first embodiment of FIG. 1 to FIG. 7 are given the same numbers in the figure, and thus, detailed explanations thereof will be omitted.

### Manufacturing Method

Next, a method for manufacturing the magnetic memory of FIG. 11 will be described.

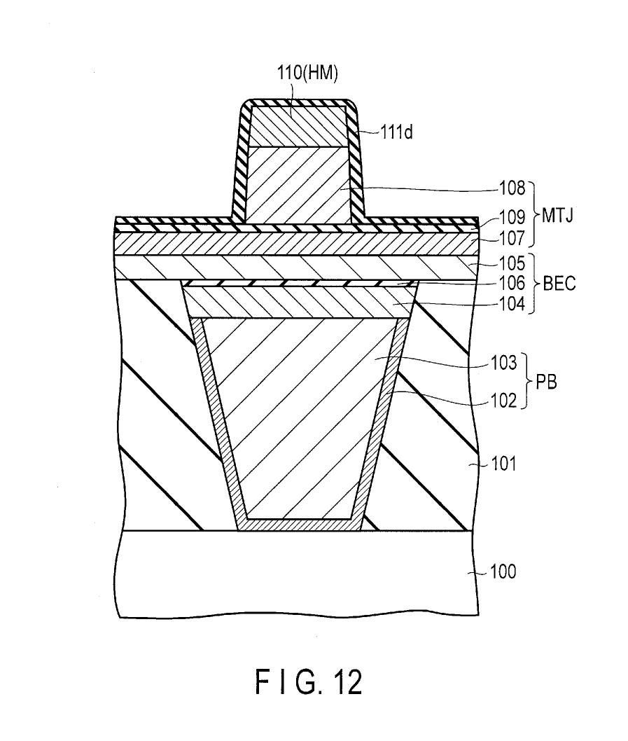

### [FIG. 12]

First, as shown in FIG. 12, the processes through which the third conductive layer (HM) 110 is formed are carried out as in the manufacturing method shown in

FIG. 2 and FIG. 3.

After that, with the third conductive layer (HM) 110 used as a mask, the second magnetic layer 108 is etched (stop-on-tunnel-barrier) until the surface of the nonmagnetic layer (tunnel barrier layer) 109 is exposed.

Next, the insulating layer 111d is formed on the nonmagnetic layer 109 by, for example, CVD. The insulating layer 111d covers the nonmagnetic layer 109, the second magnetic layer 108 and the third conductive layer (HM) 110. The insulating layer 111d is, for example, SiN.

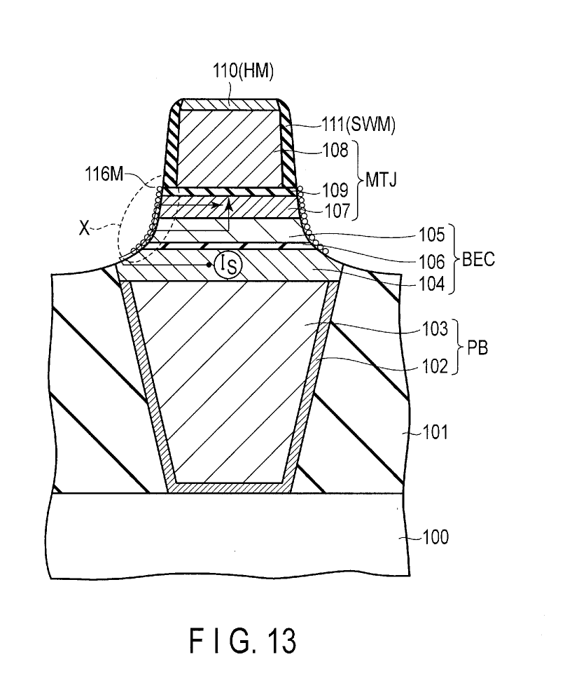

### [FIG. 13]

Next, as shown in FIG. 13, this insulating layer 111d is etched by, for example, RIE to form the sidewall mask layer (SWM) 111 covering the sidewalls of the second magnetic layer 108 and the third conductive layer (HM) 110.

Furthermore, with the third conductive layer (HM) 110 and the sidewall mask layer (SWM) 111 used as masks, the nonmagnetic layer 109 and the first magnetic layer 107 are successively etched to form the magnetoresistive element MTJ.

Then, with the third conductive layer (HM) 110 and the sidewall mask layer (SWM) 111 used as masks, the second conductive layer 105, the oxide layer 106, and the first conductive layer 104 are etched to form the lower electrode layer.

As in the first embodiment, the first conductive layer 104 to be a bottom layer of the lower electrode layer is etched, using physical etching such as IBE. Therefore, through this etching, the conductive reattachment material 116M (marks ∘ in dotted-line circle X in the figure) including the element in the first conductive layer 104 is formed on the sidewalls of the lower electrode layer, the first magnetic layer 107, and the nonmagnetic layer 109.

The reattachment material 116M is a conductive material including the element in the first conductive layer 104, and thus electrically connects the first and second conductive layers 104 and 105 and the first magnetic layer 107.

In addition, the reattachment material 116M may be attached also on the sidewall of the nonmagnetic layer (tunnel barrier layer) 109. However, in this embodiment, because the stop-on-tunnel-barrier process is adopted, the sidewall mask layer (SWM) 111 exists on the sidewall of the second magnetic layer 108. Therefore, a leak path does not appear between the first and second magnetic layers 107 and 108.

The reattachment material 116M has also a function of protecting the sidewalls of the first magnetic layer 107 and the nonmagnetic layer 109.

After that, the magnetic memory of FIG. 11 is completed by the same processes as those of the manufacturing method shown in FIG. 2 to FIG. 7.

According to the second embodiment, the current path I_{S} leads from the first conductive layer 104 to the first magnetic layer 107 through the reattachment material 116M.

On the other hand, in the first embodiment, the current path I_{S} merely connects the first and second conductive layers 104 and 105.

Therefore, in the second embodiment, a current passed through the magnetoresistive element MTJ can be increased more than in the first embodiment.

### Modification

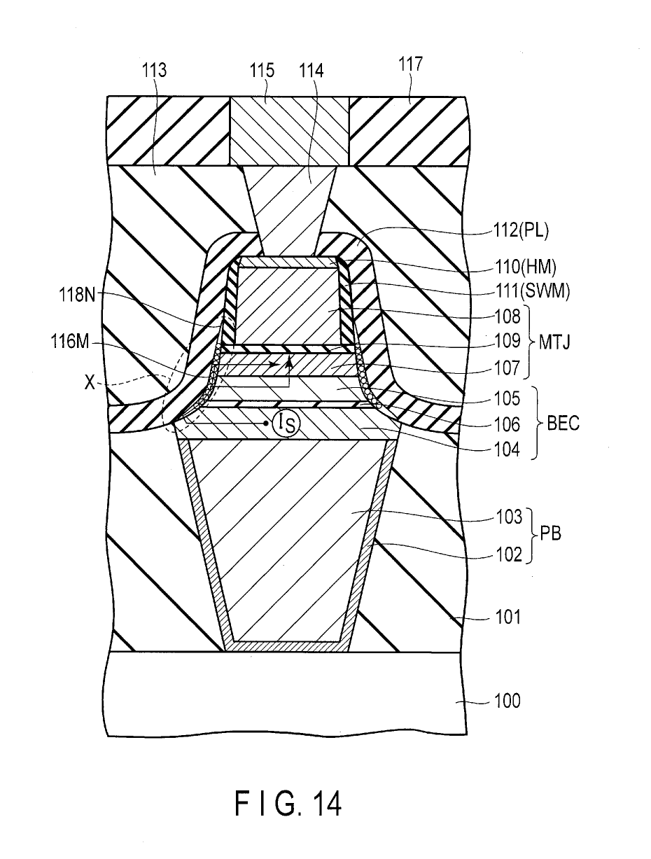

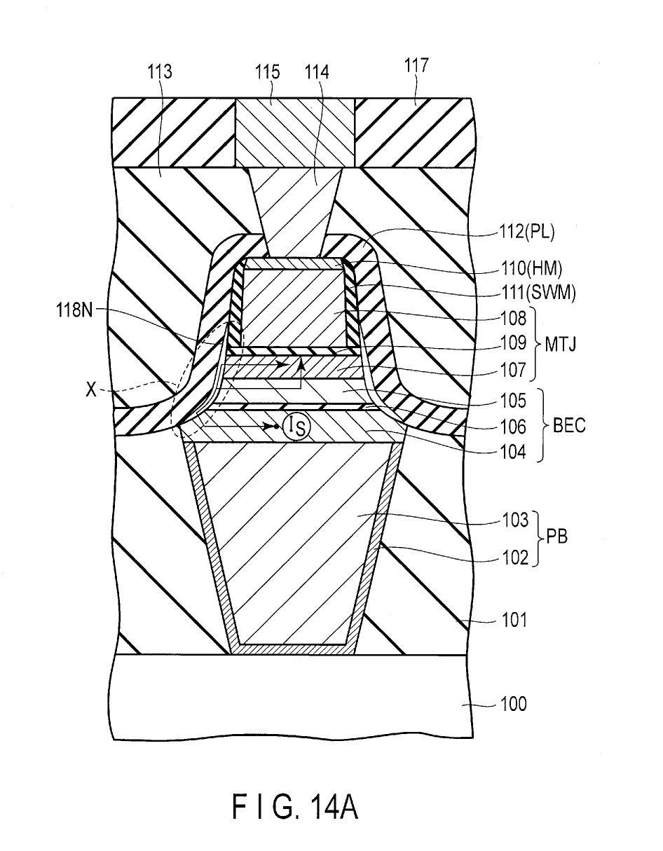

### [FIG. 14]

As shown in FIG. 14, also in the second embodiment (stop-on-tunnel-barrier process), the sidewall interconnect layer 118N covering the reattachment material 116M may be formed.

The sidewall interconnect layer 118N can be formed by, for example, the same processes as those shown in FIG. 8 and FIG. 9.

It should be noted that an electrical connection between the first and second conductive layers 104 and 105 can be made only by the sidewall interconnect layer 118N. Thus, as shown in FIG. 14A, in this modification, the reattachment material 116M may not be provided.

### Third Embodiment

A third embodiment is an embodiment of replacing the oxide layer (insulating layer) 106 of the first embodiment (FIG. 1) with a conductive oxide layer.

### Magnetic Memory

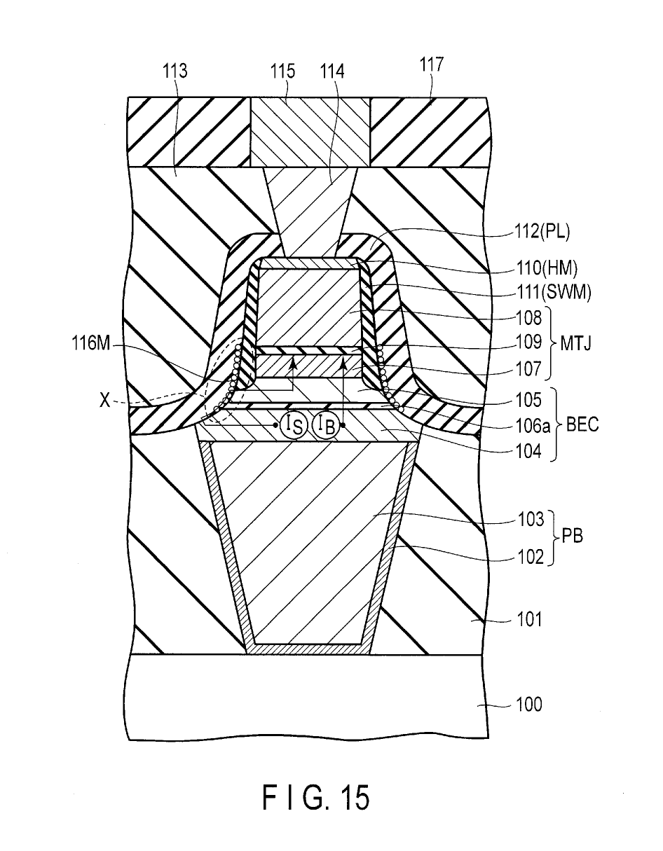

FIG. 15 shows a magnetic memory according to the third embodiment.

The third embodiment differs from the first embodiment (FIG. 1) in that a conductive oxide layer 106a is formed between the first and second conductive layers 104 and 105.

Because the other points are the same as in the first embodiment, the same elements as those of the first embodiment of FIG. 1 to FIG. 7 are given the same numbers in the figure, and thus, detailed explanations thereof will be omitted.

### Manufacturing Method

Next, a method for manufacturing the magnetic memory of FIG. 15 will be described.

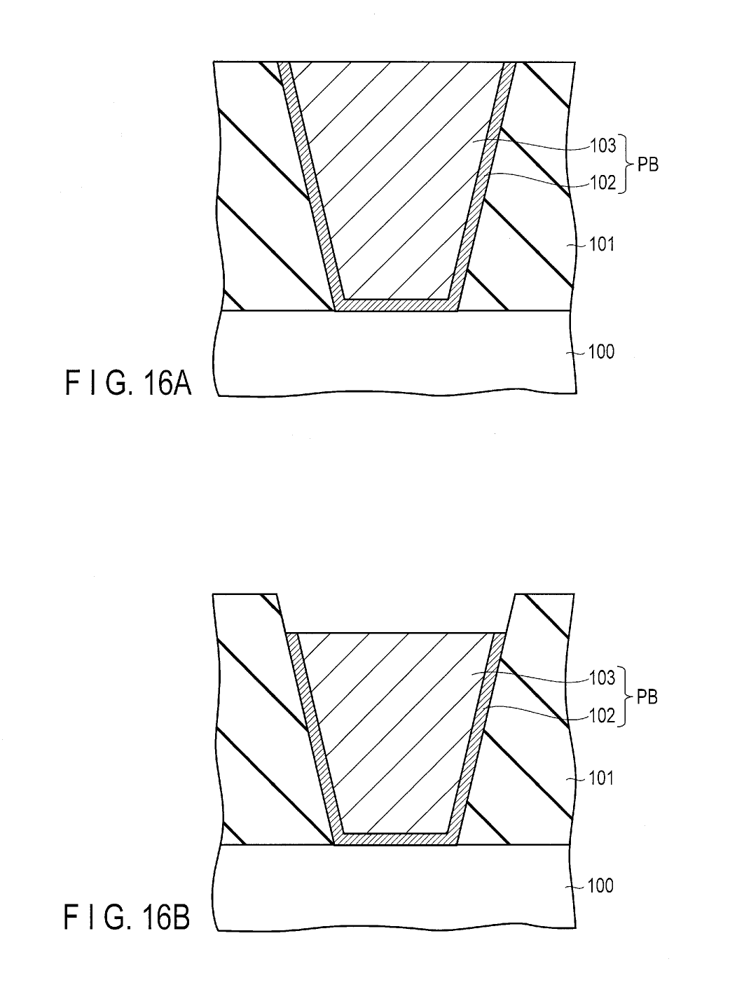

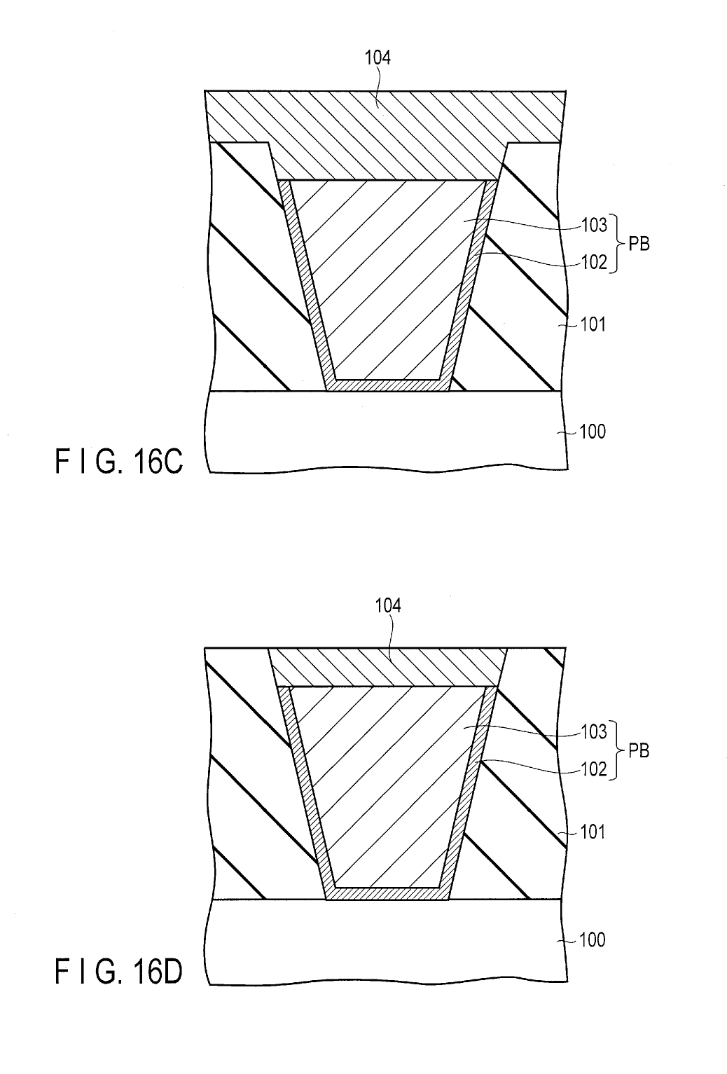

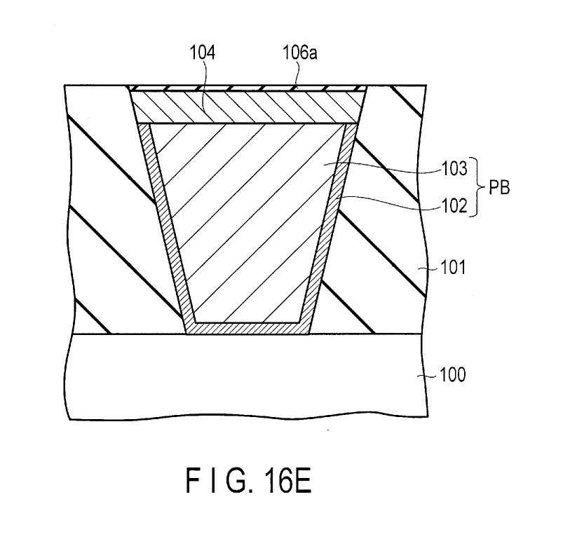

### [FIG. 16A-FIG. 16E]

First, as shown in FIG. 16A-FIG. 16E, the same processes as those of the manufacturing method of FIG. 2A-FIG. 2E are carried out until the first conductive layer 104 is formed. For the first conductive layer 104, a material which can form a conductive oxide layer by oxidation is used. The first conductive layer 104 is, for example, crystalline iridium Ir and ruthenium Ru.

After that, the first conductive layer 104 is oxidized by a wet process, etc., to form the oxide layer 106a in the amorphous state. The oxide layer 106a is a conductive oxide. The oxide layer 106a is, for example, an iridium oxide α-IrOx in the amorphous state or a ruthenium oxide αRuOx in the amorphous state.

Here, at the absolute temperature 300K, the resistivity of aluminum Al is 2.65×10⁻⁸ Ω-m, the resistivity of copper Cu is 1.68×10⁻⁸ Ω-m, the resistivity of titanium Ti is 4.2×10⁻⁷ Ω-m, the resistivity of silicon Si is 3.97×10⁻⁷ Ω-m, the resistivity of an amorphous iridium oxide α-IrOx is 5×10⁻⁷ Ω-m, and the resistivity of an amorphous ruthenium oxide α-RuOx is 2×10⁻⁷ Ω-m.

In this manner, a material used for the oxide layer 106a has the same resistivity as a metal. The oxide layer 106a functions as a conductive layer. After that, the magnetic memory is completed by the same processes as those of the manufacturing method shown in FIG. 3 to FIG. 7.

In the third embodiment, because the oxide layer 106a is conductive, the reattachment material 116M need not cover all the sidewall of the lower electrode layer. In addition, the formation of the reattachment material 116M may be skipped.

If the formation of the reattachment material 116M is skipped, an etching method of the first conductive layer 104 is not limited in particular.

In addition, in the third embodiment, two current paths I_{B} and I_{S} are provided.

Thus, in the third embodiment, a current passed through the magnetoresistive element MTJ can be increased more than in the first embodiment.

### Modification

Also in the third embodiment, the sidewall interconnect layer 118N covering the reattachment material 116M may be formed.

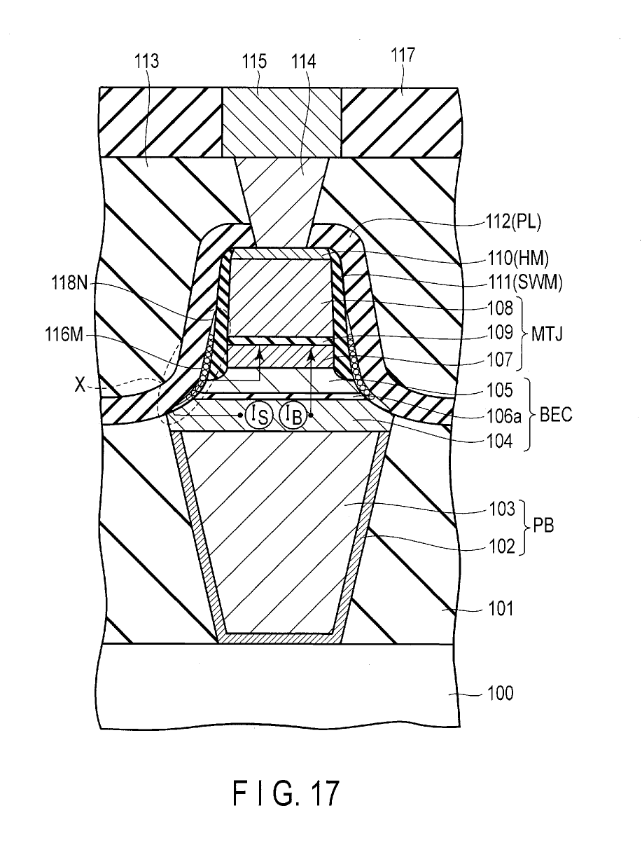

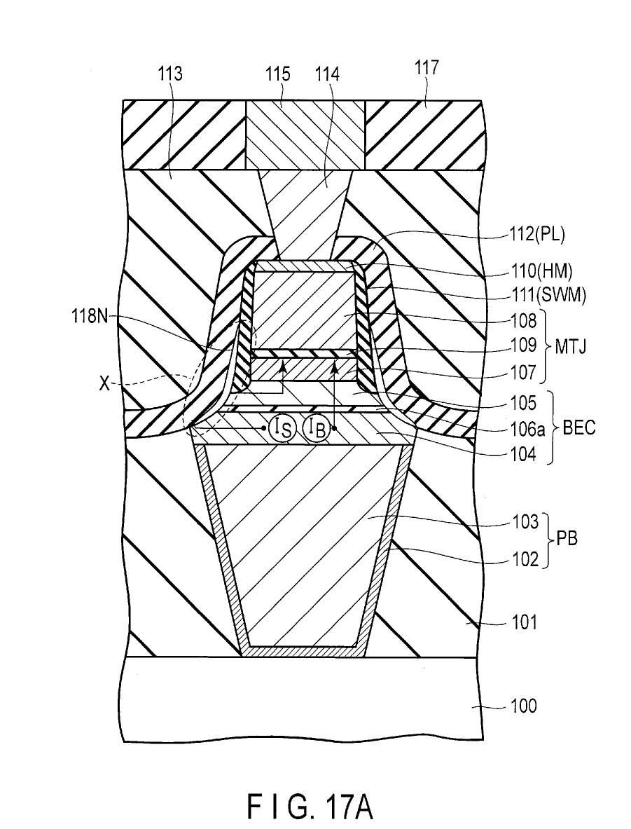

### [FIG. 17]

As shown in FIG. 17, also in the third embodiment, the sidewall interconnect layer 118N may be formed by, for example, the same processes as those shown in FIG. 8 and FIG. 9.

It should be noted that an electrical connection between the first and second conductive layers 104 and 105 can be made also only by the sidewall interconnect layer 118N. Thus, as shown in FIG. 17A, in this modification, the reattachment material 116M may not be provided.

### Fourth Embodiment A fourth embodiment is an embodiment of adopting the stop-on-tunnel-barrier process in the third embodiment.

### Magnetic Memory

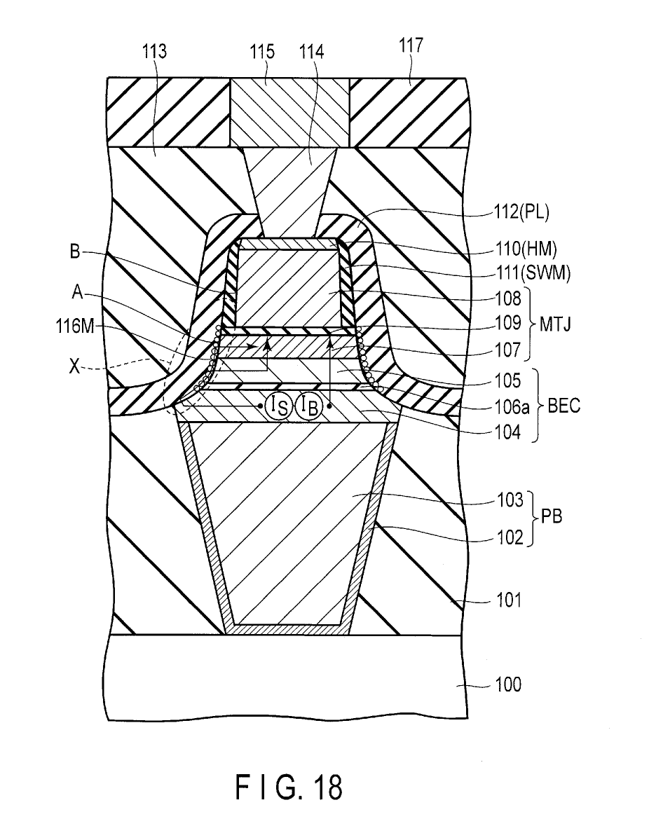

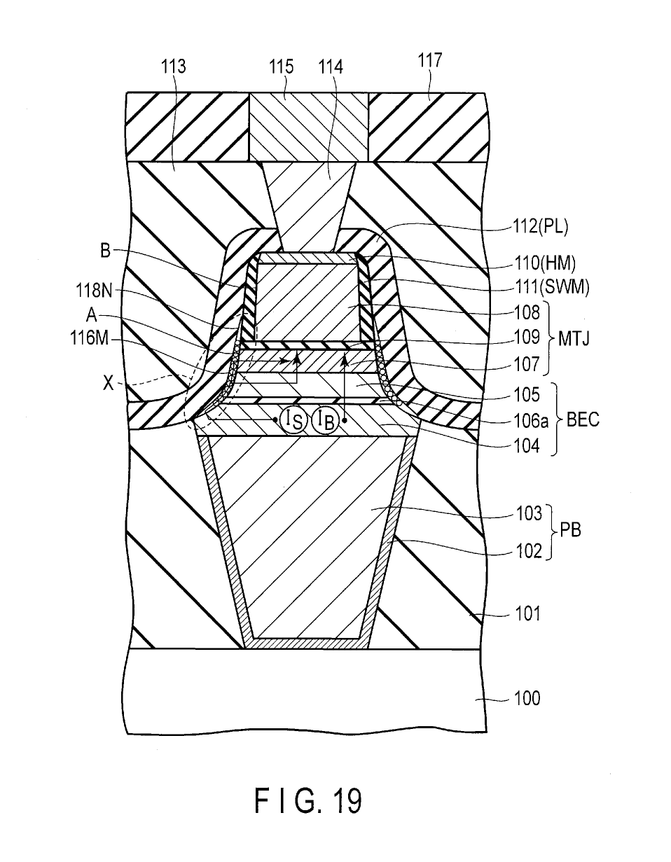

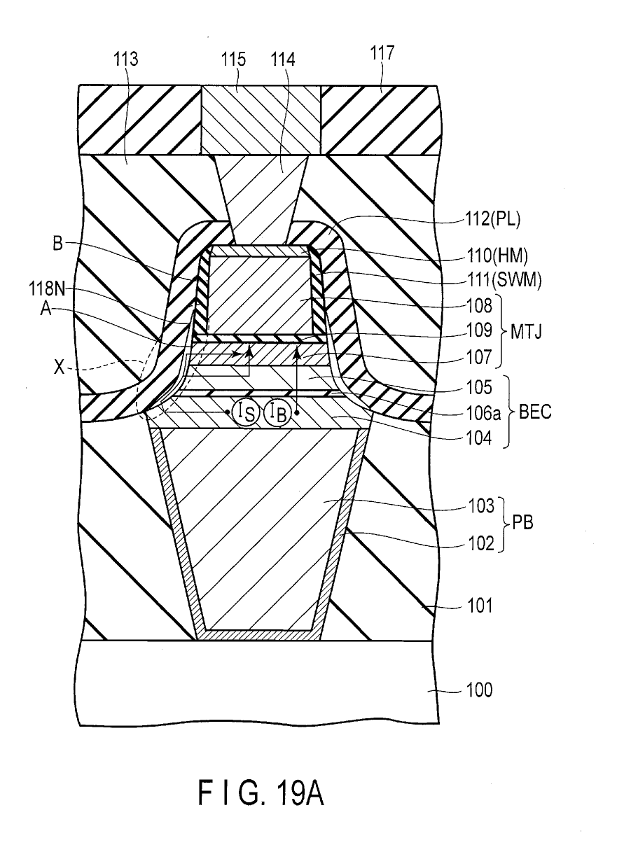

### [FIG. 18]

FIG. 18 shows a magnetic memory according to the fourth embodiment.

In fourth embodiment, the positions of the first sidewall A and the second sidewall B differ from those in the third embodiment (FIG. 15). That is, in the fourth embodiment, because the stop-on-tunnel-barrier process is adopted, the boundary between the first and second sidewalls A and B is located in the nonmagnetic layer (tunnel barrier layer) 109 or in proximity thereto.

In addition, as shown in FIG. 19, the reattachment material 116M may be covered by the sidewall interconnect layer 118N. However, because an electrical connection between the first and second conductive layers 104 and 105 can be made also only by the sidewall interconnect layer 118N, the reattachment material 116M may not be provided as shown in FIG. 19A.

Because the other points are the same as in the third embodiment, the same elements as those of the third embodiment of FIG. 15 are given the same numbers in the figure, and thus, detailed explanations thereof will be omitted.

### Fifth Embodiment

A fifth embodiment is an embodiment of forming, between the first magnetic layer 107 and the second conductive layer 105, an underlying layer 119 having greater resistivity than those of the layers in the first to fourth embodiments.

### Magnetic Memory

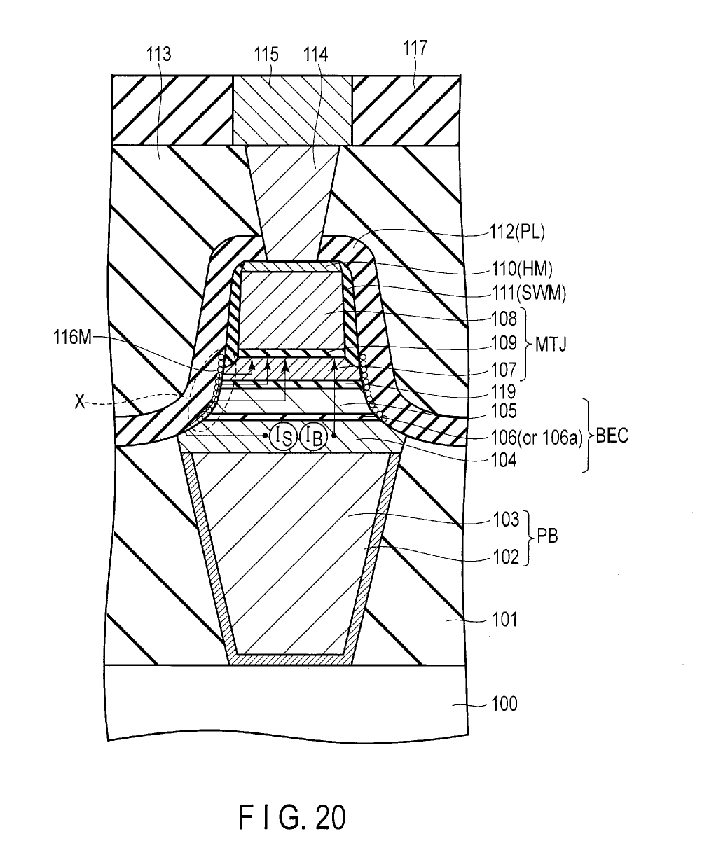

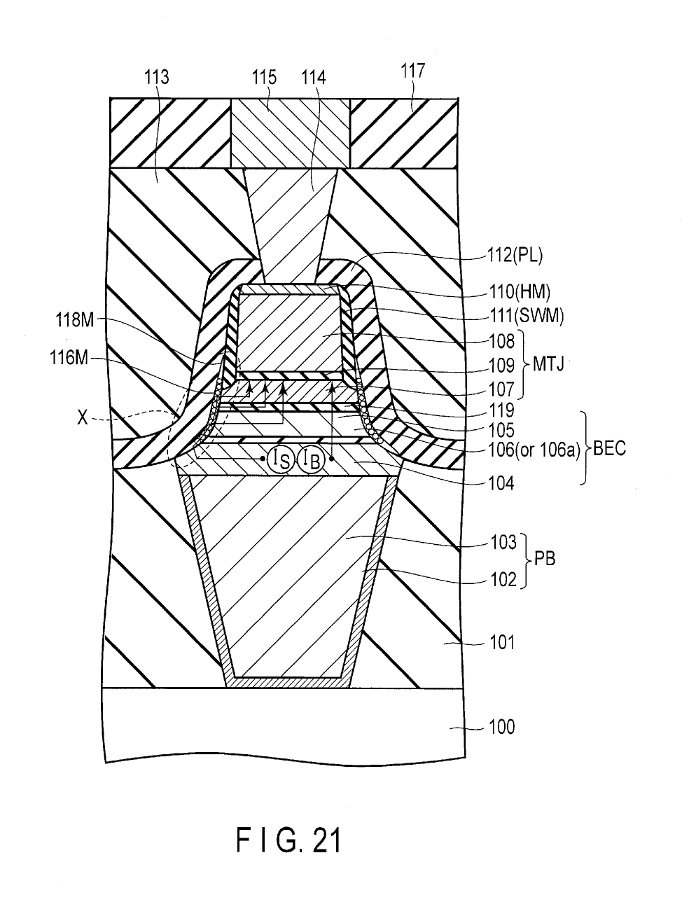

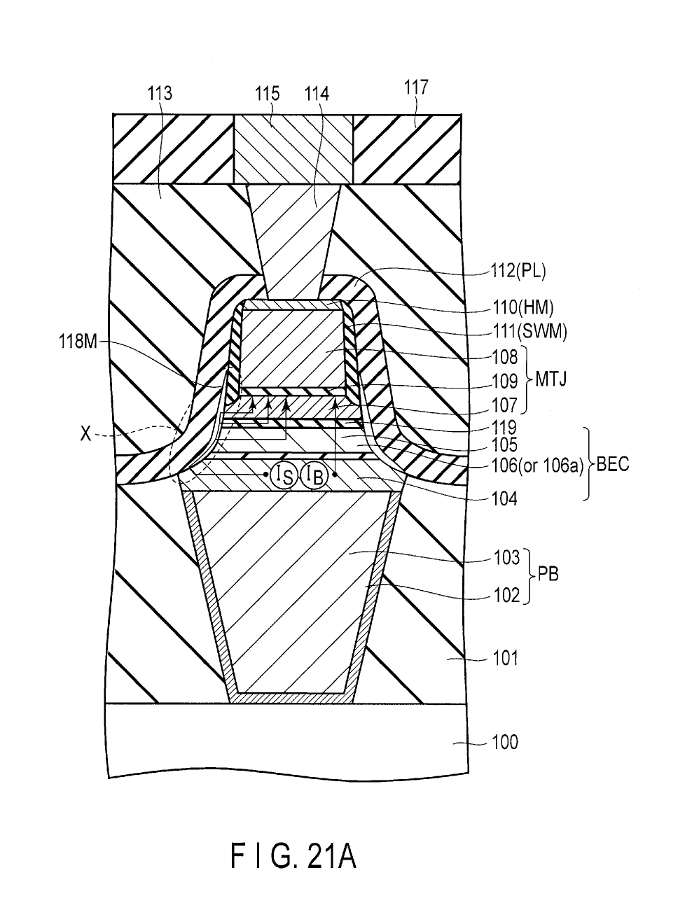

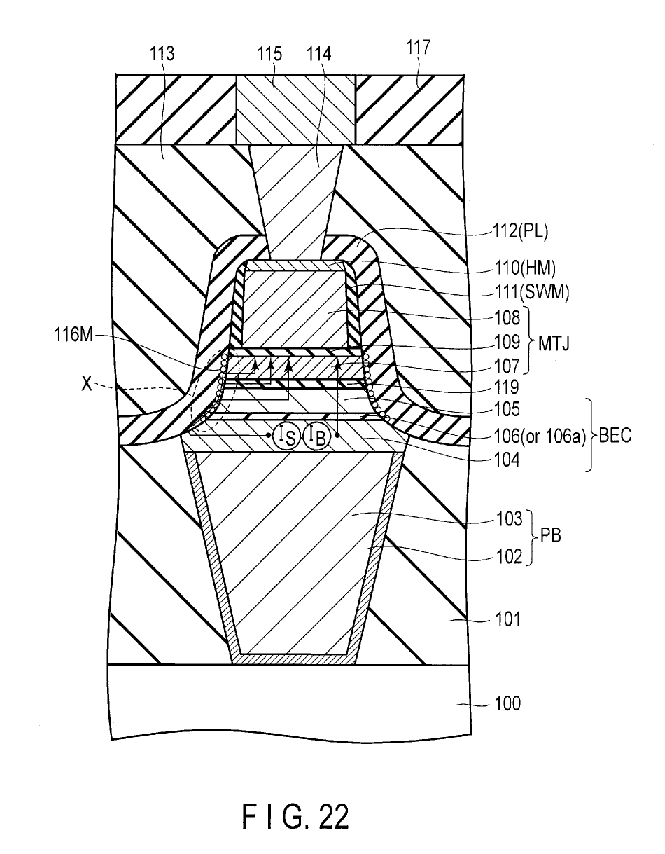

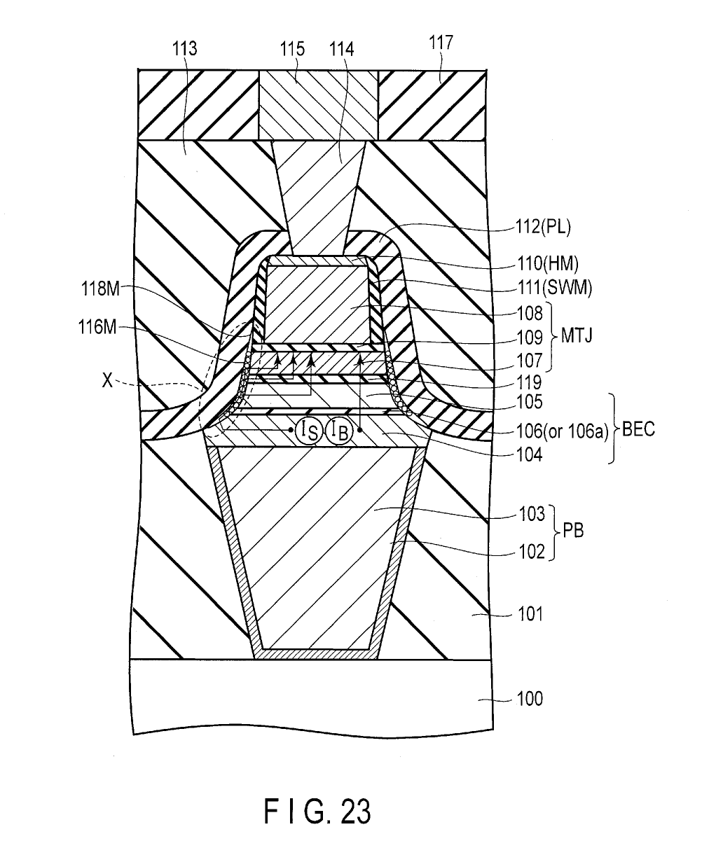

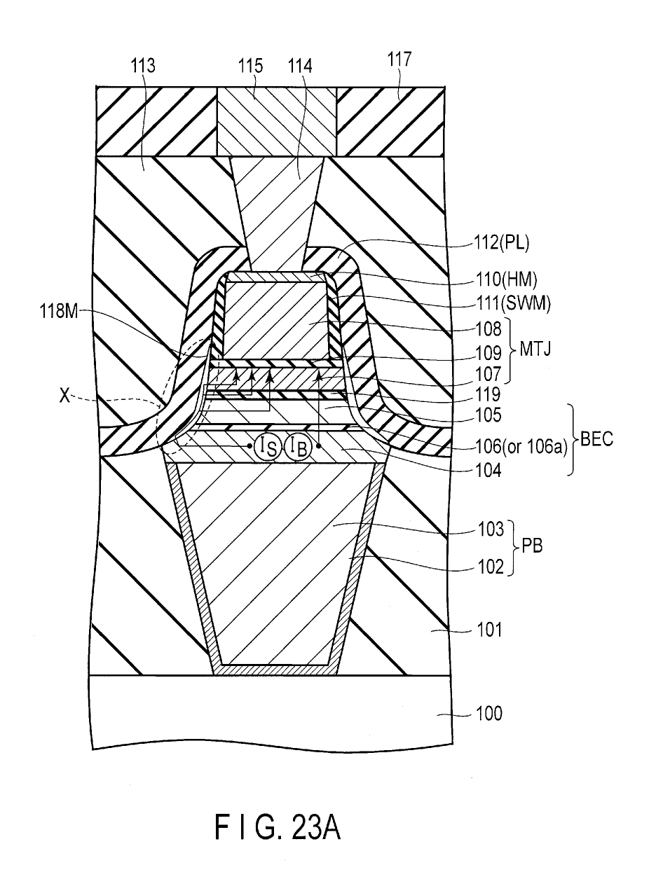

FIG. 20 to FIG. 23 show a magnetic memory according to the fifth embodiment.

In FIG. 20, the underlying layer 119 is further provided between the first magnetic layer 107 and the second conductive layer 105 in the first and third embodiments (FIG. 7 and FIG. 15).

In FIG. 21, in the modifications of the first and third embodiments (FIG. 10 and FIG. 17), the underlying layer 119 is further provided between the first magnetic layer 107 and the second conductive layer 105. Moreover, FIG. 21A shows an example of making an electrical connection between the first and second conductive layers 104 and 105 only by the sidewall interconnect layer 118N and without the reattachment material 116M.

In FIG. 22, the underlying layer 119 is further provided between the first magnetic layer 107 and the second conductive layer 105 in the second and fourth embodiments (FIG. 11 and FIG. 18).

In FIG. 23, in the modifications of the second and fourth embodiments (FIG. 14 and FIG. 19), the underlying layer 119 is further provided between the first magnetic layer 107 and the second conductive layer 105. Moreover, FIG. 23A shows an example of making an electrical connection between the first and second conductive layers 104 and 105 only by the sidewall interconnect layer 118N and without the reattachment material 116M.

The underlying layer 119 improves the crystallinity of the magnetoresistive element MTJ. The underlying layer 119 is, for example, nitride such as aluminum nitride AlN. Aluminum nitride AlN has a great ionization degree and prevents diffusion of water (H₂O) and oxygen (O₂). To improve the film quality and the anti-diffusion function of the aluminum nitride AlN, it is desirable that the aluminum nitride AlN be formed at 250° C. or more. Besides, AlN and MgO are also other candidate materials.

Because the other points are the same as in the first to fourth embodiments, the same elements as those of the first to fourth embodiments are given the same numbers in the figure, and thus, detailed explanations thereof will be omitted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory comprising:
an interconnect layer;
a first conductive layer on the interconnect layer, the first conductive layer including a metal;
an oxide layer on the first conductive layer;
a second conductive layer on the oxide layer;
a magnetoresistive element on the second conductive layer, the magnetoresistive element including a first magnetic layer, a second magnetic layer and a nonmagnetic layer between the first and second magnetic layers; and
a deposited material on a sidewall of the oxide layer, the deposited material including the metal.

2. The memory of claim 1, wherein the deposited material electrically connects the first and the second conductive layer.

3. The memory of claim 1, wherein the first conductive layer has crystallinity.

4. The memory of claim 1, wherein the oxide layer includes an amorphous state.

5. The memory of claim 1, wherein the oxide layer includes an oxide of the metal included in the first conductive layer.

6. The memory of claim 1, wherein the oxide layer is a conductive oxide.

7. The memory of claim 1, wherein the oxide layer is a nonconductive oxide.

8. The memory of claim 1, wherein the metal includes any of tantalum, iridium and ruthenium.

9. The memory of claim 1, further comprising a sidewall interconnect layer which covers the deposited material including the metal and is provided on sidewalls of the first and second conductive layers and the sidewall of the oxide layer.

10. The memory of claim 1, further comprising an underlying layer of the magnetoresistive element, the underlying layer being provided between the second conductive layer and the magnetoresistive element.

11. The memory of claim 10, wherein the deposited material including the metal is disposed on a sidewall of the underlying layer and electrically connects sidewalls of the second conductive layer and the magnetoresistive element.

12. The memory of claim 1, wherein the interconnect layer is a contact plug provided in a contact hole.

13. A magnetic memory comprising:
an interconnect layer;
a first conductive layer on the interconnect layer, the first conductive layer including a metal;
an oxide layer on the first conductive layer;
a second conductive layer on the oxide layer;
a magnetoresistive element on the second conductive layer, the magnetoresistive element including a first magnetic layer, a second magnetic layer and a nonmagnetic layer between the first and second magnetic layers; and
a sidewall interconnect layer provided on a sidewall of the oxide layer.

14. The memory of claim 13, wherein the sidewall interconnect layer electrically connects the first and the second conductive layer.

15. The memory of claim 13, wherein the first conductive layer has crystallinity.

16. The memory of claim 13, wherein the oxide layer of the first conductive layer includes an amorphous state.

17. The memory of claim 13, wherein the oxide layer includes an oxide of the metal included in the first conductive layer.

18. The memory of claim 13, wherein the metal includes any of tantalum, iridium and ruthenium.

19. The memory of claim 13, further comprising an underlying layer of the magnetoresistive element, the underlying layer being provided between the second conductive layer and the magnetoresistive element.

20. The memory of claim 19, wherein the sidewall interconnect layer is disposed on a sidewall of the underlying layer and electrically connects sidewalls of the second conductive layer and the magnetoresistive element.

21. The memory of claim 13, wherein the interconnect layer is a contact plug provided in a contact hole.

22. A method for manufacturing a magnetic memory comprising:
forming a first conductive layer on an interconnect layer, the first conductive layer including a metal;
forming an oxide layer on the first conductive layer;
forming a second conductive layer on the oxide layer;
forming a magnetoresistive element on the second conductive layer, the magnetoresistive element including a first magnetic layer, a second magnetic layer and a nonmagnetic layer between the first and second magnetic layers;
patterning the magnetoresistive element, the second conductive layer, the oxide layer and the first conductive layer by physical etching; and
forming a deposited material on a sidewall of the oxide layer, the deposited material including the metal.

23. The memory of claim 22, wherein the deposited material electrically connects the first and the second conductive layer.
